(19) United States
(12) Patent Application Publication
(10) Pub. No.: US 2008/0179285 A1
(43) Pub. Date: Jul. 31, 2008

(54) Wafer holding device for etching process and method for controlling etch rate of a wafer

(75) Inventors: Hao Li, Dongguan (CN); HongTao Ma, Dongguan (CN); HongXin Fang, Dongguan (CN); XiaoFeng Qiao, Dongguan (CN)

Correspondence Address: NIXON & VANDERHYE, PC, 901 NORTH GLEBE ROAD, 11TH FLOOR, ARLINGTON, VA, 22203, US

(73) Assignee: SAE Magnetics (H.K.) Ltd., Hong Kong (CN)

(21) Appl. No.: 11/657,523

(22) Filed: Jan. 25, 2007

(51) Int. Cl. H01L 21/3065; H01L 21/683

(52) U.S. Cl. 216/63; 156/345.51; 204/192.34

(57) ABSTRACT

A wafer holding device for etching process, includes a base pallet; a cover pallet disposed on the base pallet, the cover pallet having at least one receiving hole defined therein; a base pad located on the base pallet and contained in the receiving hole; and a wafer jig placed on the base pad and contained in the receiving hole. At least one gas-diluting recess is formed in a surface of the cover pallet, the surface being spaced away from the base pallet, the gas-diluting recess being communicated with the receiving hole to dilute byproduct gases generated during the etching process. The invention also discloses a method for controlling etch rate of a wafer to be etched during an etching process.

### FIELD OF THE INVENTION

The present invention relates to a device used in manufacturing semiconductor product, and more particularly to an improved wafer holding device used in an ion etching process so as to improve etching uniformity of a wafer handled by the process, and to a method for controlling etch rate of a wafer during an etching process.

### BACKGROUND OF THE INVENTION

Semiconductor products for example very large scale integration circuit (VLSI) chips have been widely used in many industry fields such as information technology and telecommunication technology for decades of years. Besides VLSI chips, other semiconductor products may include magnetic sliders incorporated in a hard disk drive unit to read/write digital information from/into an information recording disk, micro electromechanical system (MEMS) utilized in field such as biotechnology for performing predefined actions in very small three-dimensional environment and so on.

Almost all above semiconductor products are manufactured from a wafer such as silicon wafer. Fabrication of these products may involve numerous steps such as wafer cutting, lapping, etching, deposition or the like. In these steps, etching is one of the most important steps in entire fabrication of the product. Normally, a wafer to be processed is positioned in a vacuum chamber and then subjected to physical/chemical ion etching/deposition to form certain topographical feature on the wafer.

As for etching process, a variety of etching processes are available in the market including reactive ion etching (RIE) and ion mill (IM) and so on. Among these technologies, RIE has been extensively employed in many fields e.g. science research and microelectronic fabrication, semiconductor manufacturing and similar field for years. The advantages of RIE are good etching selectivity and comparable etching feature profile controlling.

In recent years, RIE techniques have been also widely used in the manufacture of Giant Magnetic Resistance head (GMRH) and Tunnel Magnetic Resistance (TMRH) for hard disk drives. RIE includes high-density plasma (HDP) RIE system and inductively coupled plasma (ICP) HDP RIE system. Cluster Etch RIE System of Surface technology systems company (STS) is a typical ICP HDP RIE system and is extensively used in fabrication of GMRHs and TMRHs.

Typically, when subjected to an ion etching process, a wafer is placed on a wafer holding device so as to be handled by a physical/chemical process, therefore reducing etching quality variation among the whole wafer surface. Reduction in etching quality variation is a key performance to process control. A typical wafer holding device for this purpose is shown in FIGS. 1a-1c. As shown in figures, the wafer holding device 100 comprises a base pallet 102 of circular shape, a cover pallet 104 with three circular receiving holes 101 defined therein and covered on the base pallet 102, a base pad 106 mounted on the base pallet 102 and contained in each receiving hole 101, and a wafer jig 108 placed on the base pad 106 and accommodated in respective receiving hole 101 of the cover pallet 104.

Wafers 20 are bonded to respective wafer jigs 108 (in this case, wafer jigs of 4″ diameter are used) and contained in respective receiving holes 101. For simplicity, a plurality of row bars is taken as objects to be etched in the etching process. The row bars are obtained from separation of a wafer and are used to make GMRHs/TMRHs incorporated in hard disk drives. Each row bar has a plurality of slider bodies (not shown) each of which will be processed to form an individual GMRH/TMRH, and normally, 56 row bars are bonded on a wafer jig 108 in a parallel and compact manner. As shown in FIG. 1c, these row bars may have different lengths, for example, the 1^{st} through 11^{th} row bars and the 47^{th} through 56^{th} row bars are of short length and therefore, are referred as to short row bars hereinafter, whereas the row bars from 12^{th} to 46^{th} are of a longer length and therefore, are named as long row bars.

After etched, certain recessed feature is formed on respective row bar. FIGS. 2a-2b indicates etching depth/rate curves of different row bars mounted on a same wafer jig. In FIG. 2a, curve 201 represents etching depths of the short row bars (for example row bars from 1^{st} to 11^{th} and from 47^{th} to 56^{th}) along their length direction, while curves 202, 203 represent those of the long row bars (such as the row bars from 12^{th} to 46^{th}). Similarly, in FIG. 2b, curves 204, 205 show overall etching uniformity of short row bars, while curves 206 show overall etching uniformity of long row bars. It can be clearly seen that both distal ends 207 (as shown in phantom circles) of each short row bar renders a lower etching rate than that of the central region thereof (not labeled), and comparatively, both distal ends 208 (as shown in phantom circles) of each long row bar renders a higher etching rate than that of the central region thereof (not labeled). For most short row bars, the etching rate at both ends clearly slower than that at the central region, i.e., these row bars have low etching uniformity along their entire length. The reasons are explained as follows in conjunction with FIGS. 3a-3b.

FIG. 3a illustrates main principle of an etching process. The wafer 20 to be processed is coated with a layer of photo-resist 30 so as to protect certain area where etching process should not happen. The etching process only occurs at region not covered by the photo-resist 30. In general, an ideal dry etching procedure based only on chemical reaction mechanism could be presented as several steps: 1) Reactive gases come into a process chamber; 2) Etchant (Free Radical/reactive species, neutral ion etc.) is created (numeral 301 in figure); 3) Etchant is transferred and adsorbed on the substrate surface 20 ; 4) Etchant 302 stops at substrate surface 20; 5) Etchant/substrate are reacting with each other and then create byproduct (numeral 303 in figure); 6) byproduct takes off the substrate surface 20; 7) Byproduct is removed from the substrate surface 20. Finally, micro-recess 304 is formed on the wafer surface. These numerous micro-recesses 304 collectively constitute feature on the wafer surface. When the reactive neutral species act by themselves, the process is called chemical etching, and when the reactive neutral species and ions act in a synergistic fashion, it is called ion-enhanced etching, such as RIE.

During above etching process, the radical species 301 and byproduct exist mainly in gas phase and their density or concentration has great influence on etching rate/depth of the row bars. Higher radical concentration will cause etching rate faster; but heavier non-vapor byproduct density (such as A1F3, etc) will redeposit on substrate surface 20 and cause etching rate slower. Referring to FIG. 3b, on one hand, if the cover pallet 104 is higher than the wafer 20, the radical species gas flow L at a distal end of a row bar will be baffled by inner wall of the receiving hole (not labeled) of the cover pallet 104, and consequently, the radical species concentration/density of the gas at this location will be decreased and more byproduct will redeposit on the substrate, therefore, etching rate at this distal end will be slower than the central region of the row bar where density of radical species and byproduct gas maintains substantially unchanged. On the other hand, if the cover pallet 104 is lower than the wafer 20, the radical species byproduct gas flow R at an opposite distal end will flow faster than at the central region, thus bringing more radical species to expedite the reaction, since the gas flows faster than central region and accordingly, the density of byproduct at this distal end is smaller than the central region due to byproduct stopping time is shorter, and accordingly, etching rate at this distal end will get faster than the central region.

The above phenomena is also called step effect, as it is the step between the inner wall of the receiving hole and distal ends of a wafer that changes the etching rate at two distal ends of a row bar. This step effect has large influence on the short row bars than the long row bars, because the distal ends of the short row bars are closer to the inner walls of the receiving hole than the long row bars and, Referring to FIGS. 1a-1c, as the distal ends of short row bars are closer to the inner wall of the receiving hole 101 of the cover pallet 104 than do long row bars, step effect will reduce etching rate of the short row bars at their distal ends.

Summarily speaking, as conventional wafer holding device design doesn't employ surface topographical effect of the wafer holding device on the gas micro flow, and thus bring disadvantageous reaction rate variance. Correspondingly, conventional etching method utilizing a conventional wafer holding device fails to provide a controllable etch rate for a wafer being etched.

Thus, there is a need for an improved system that does not suffer from the above-mentioned drawbacks.

### SUMMARY OF THE INVENTION

A main object of the invention is to provide a wafer holding device for etching process, which can provide etching environment in which radical and byproduct gas has uniformity density everywhere. In other word, the invention makes effective use of geographic feature of the wafer holding device to suppress or compensate local etching rate deviation. Therefore, the invention improves overall etching uniformity of a wafer thus formed. Of course, it also gets special etching rate profile according to certain need.

To achieve above objects, A wafer holding device for etching process, includes a base pallet; a cover pallet disposed on the base pallet, a base pad located on the base pallet and contained in the receiving hole; and a wafer jig placed on the base pad and contained in the receiving hole. At least one gas-diluting recess is formed in a surface of the cover pallet, the surface being spaced away from the base pallet, the gas-diluting recess being communicated with the receiving hole to dilute byproduct gases generated during the etching process.

The number of the gas-diluting recesses may be four, the receiving hole may be a circular receiving hole, and the four gas-diluting recesses may be evenly distributed around the circular receiving hole. In addition, the gas-diluting recess may be of approximately a triangular shape.

The cover pallet is of a circular shape, the number of the receiving holes is three, and the receiving holes are evenly distributed around the center of the circular cover pallet. The cover pallet is made of aluminum or stainless steel or ceramic material.

The total thickness of the cover pallet is changeable. It depends on the process condition. For example, when a recipe of 3 mTorr, CF4 15 sccm STS RIE is taken, the total thickness is 3.0˜5.0 mm, and the gas-diluting recess is 1.0˜2.5 mm thick. Moreover, the relative position between the top surface of the cover pallet and the top surface of the wafer can be adjusted to get desired etch rate across the entire wafer. The gas-diluting recess is key controlling point and depends closely on the process condition so as to match/adjust etching rate uniformity.

The invention also provides for a method for controlling etch rate of a wafer. The wafer has a surface to be etched at its peripheral region. The method comprises the steps of: providing a wafer holding device comprised of a base pallet and a cover pallet mounted on the base pallet, the cover pallet having a receiving hole defined therein; placing the wafer in the receiving hole such that a step height is formed between an inner sidewall of the receiving hole and the peripheral region of the wafer; etching the surface to be etched of the wafer; changing the step height to adjust etching rate of the wafer at its peripheral region.

The wafer holding device further comprises a base pad mounted on the base pallet and contained in the receiving hole, and a wafer jig mounted on the base pad. The wafer is mounted on the wafer jig.

Changing the step height comprises increasing the distance between the surface to be etched of the wafer and the base pallet such that the surface to be etched is higher than the inner sidewall of the cover pallet. Changing the step height may also comprise decreasing the distance between the surface to be etched of the wafer and the base pallet such that the surface to be etched is lower than the inner sidewall of the cover pallet.

Changing the step height is accomplished by adjusting thickness of the base pad. Namely, the step height can be increased if a thick base pad is used in the wafer holding device such that the surface to be etched is higher than the cover pallet; and the step height can be decreased by using a thinner base pad so that the surface to be etched of the wafer is lower than the cover pallet.

Other aspects, features, and advantages of this invention will become apparent from the following detailed description when taken in conjunction with the accompanying drawings, which are a part of this disclosure and which illustrate, by way of example, principles of this invention.

### BRIEF DESCRIPTION OF THE DRAWINGS

The accompanying drawings facilitate an understanding of the various embodiments of this invention. In such drawings:

FIG. 1a shows a top plan view of a conventional wafer holding device for ion etching process;

FIG. 1b shows a cross-sectional view of the wafer holding device of FIG. 1a along line A-A;

FIG. 1c shows a top plan view of a wafer jig on which a plurality of row bars obtained by cutting a wafer is arranged in a compact and parallel manner;

FIG. 2a shows several curves, each curve indicating etching depths of a particular row bar shown in FIG. 1c at different positions along its entire length;

FIG. 2b shows a diagram illustrating etching rate of different row bars shown in FIG. 1c along their length direction;

FIG. 3a illustrates main principle of ion etching process;

FIG. 3b shows a kinetic model of byproduct gas movement during an ion etching process;

FIG. 4a shows a top plan view of a wafer holding device used in an etching process according to an embodiment of the invention;

FIG. 4b shows a cross-sectional view of the wafer holding device shown in FIG. 4a along line A-A;

FIG. 4c shows a cross-sectional view of a cover pallet shown in FIG. 4a;

FIG. 5a shows a curve illustrating etching depths of different row bars mounted on the same wafer jig of a conventional wafer holding device;

FIG. 5b shows several curves each representing etching depths of a particular row bar along its entire length, the row bars being mounted on the same wafer jig of a conventional wafer holding device;

FIG. 5c shows several curves each representing etching depths of a particular row bar along its entire length, the row bars being mounted on the same wafer jig of a wafer holding device according to the invention;

FIG. 5d shows a diagram illustrating overall etching uniformity data of a group of row bars obtained by conventional technology and the invention respectively; and

FIG. 5e shows a diagram illustrating batch etching uniformity data of a batch of row bars obtained by conventional technology and the invention respectively.

### DETAILED DESCRIPTION OF ILLUSTRATED EMBODIMENTS

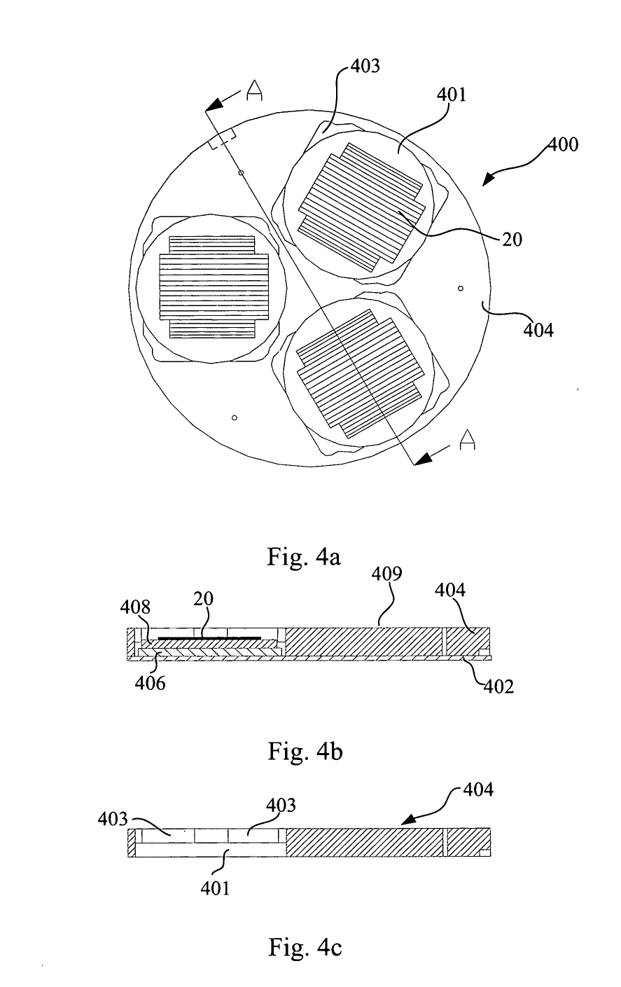

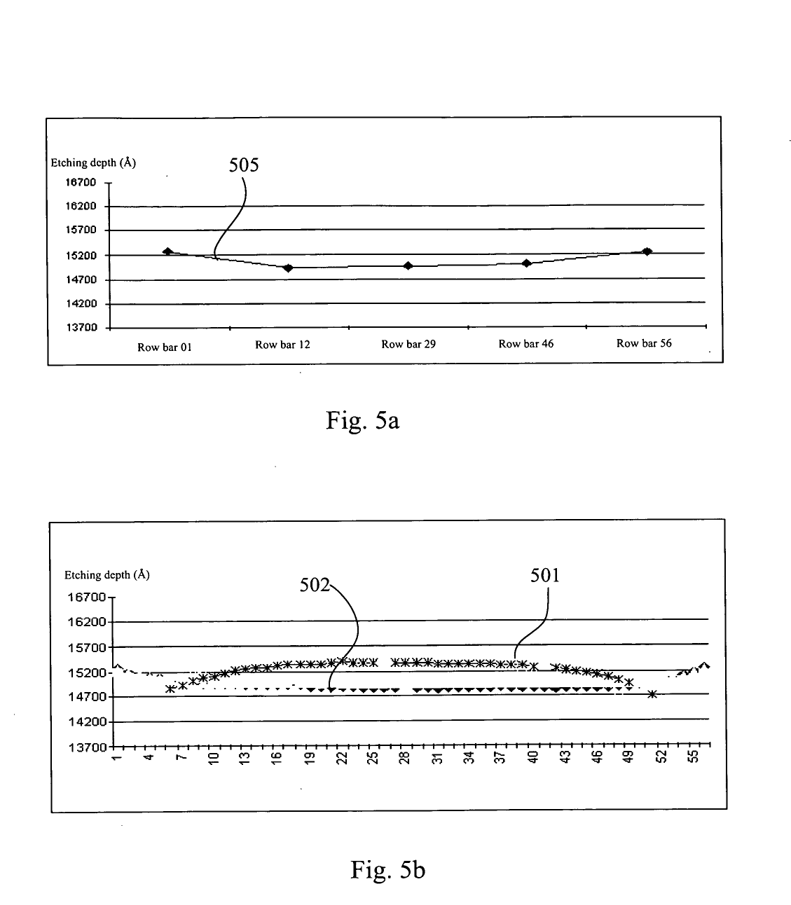

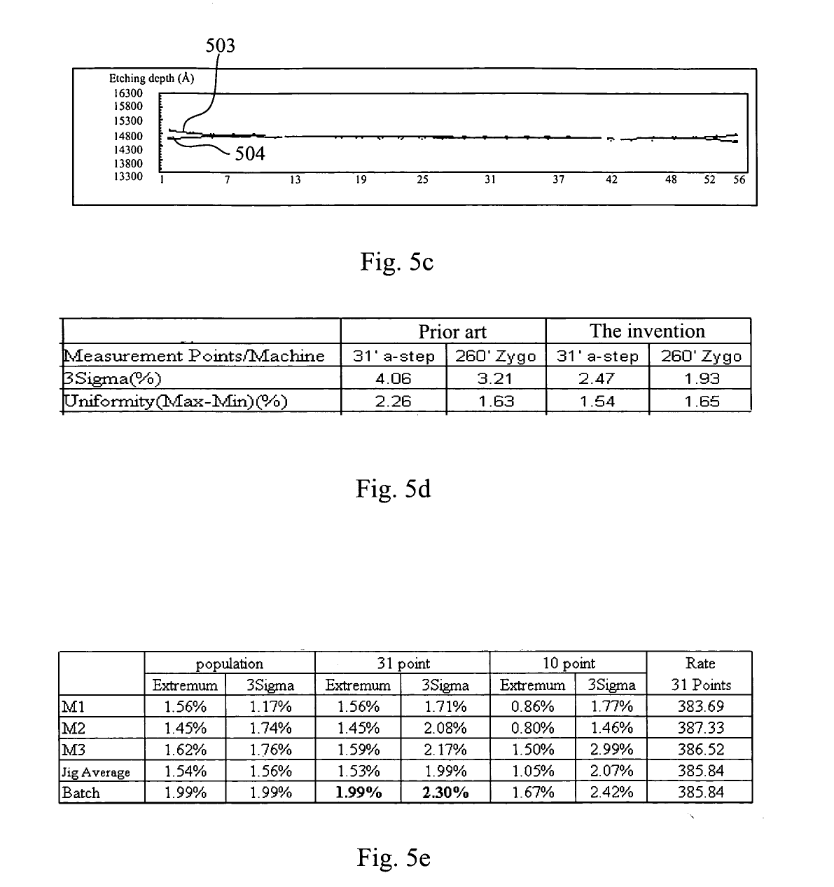

The invention provides a wafer holding device used in an etching process for assisting in improving etching uniformity of a wafer being handled by the process. FIGS. 4a-4c and 5a-5e show an embodiment of the invention. Referring to FIGS. 4a-4c, a wafer holding device 400 includes a base pallet 402; a cover pallet 404 disposed on the base pallet 402, the cover pallet 404 having three receiving hole 401 defined therein; a base pad 406 located on the base pallet 402 and contained in the receiving hole 401 of the cover pallet 404; and a wafer jig 408 placed on the base pad 406 and contained in the receiving hole 401.

The base pallet 402 may be made of stainless steel or aluminum and is used to support all other components, i.e., the cover pallet 404, the base pad 406 and the wafer jig 408. The cover pallet 404 may also be constructed by aluminum, ceramic material or stainless steel and is used for accommodating the base pad 406, the wafer jig 408 and a wafer 20 to be processed therein. The receiving holes 401 are evenly distributed around the center of the circular cover pallet 404. The base pad 404 is sandwiched between the base pallet 402 and the wafer jig 408 for adjusting vertical position of the wafer 20 with respect to the receiving hole 401 of the cover pallet 404. The wafer jig 408 is mounted on the base pad 404 and contained in the receiving hole 401. Suitable material for example silicon or ceramic or stainless steel may be used to form the wafer jig 408. The wafer jig 408 carries the wafer 20 thereon by proper manner such as adhesive.

In addition, the base pallet 402, the cover pallet 404 and the base pad 406 may all be of a circular shape. Also, each receiving hole 401 of the cover pallet 404 may be of a circular shape so as to conveniently accommodate the base pad 406 and the wafer jig 408.

Particularly, four gas-diluting recesses 403 are formed in a top surface 409 of the cover pallet 404. The top surface 409 is spaced away from the base pallet 402. These gas-diluting recesses 403 are evenly distributed around the center of respective receiving hole 401and communicate the receiving hole 401 so as to dilute byproduct gas generated during the etching process. In this embodiment, the gas-diluting recesses 403 are of approximately a triangular shape.

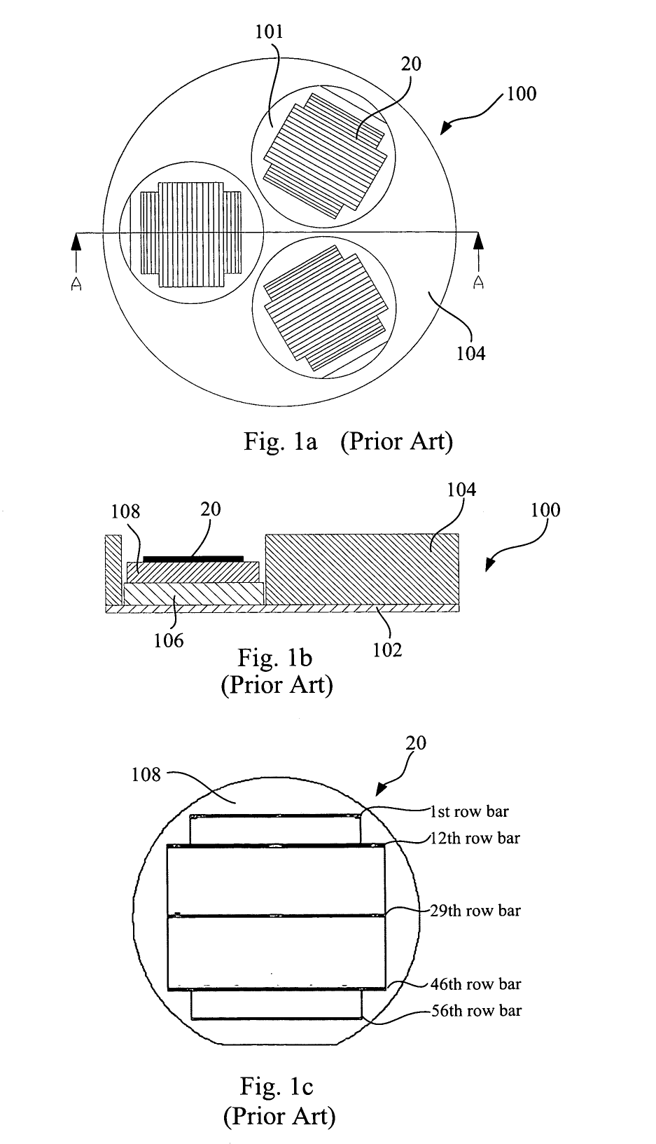

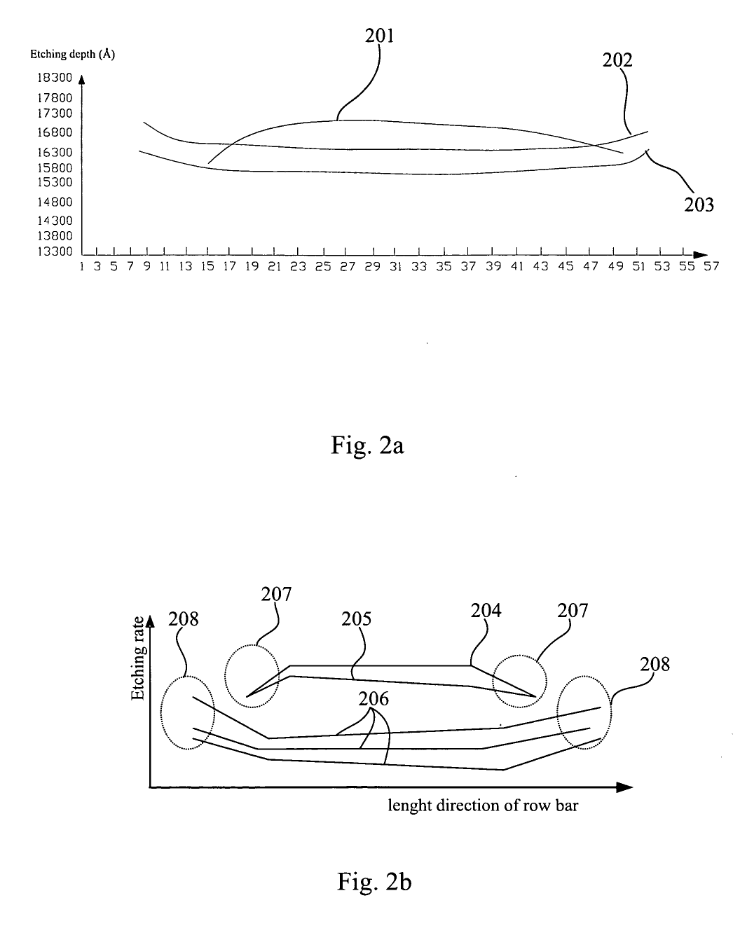

For better understanding advantages of the invention, the row bars shown in FIG. 1c are taken as objects to be etched in an etching process. After the row bars (not labeled) are secured on respective wafer jig 408 of the wafer holding device 400, the row bars are subjected to the etching process. During the above process, byproduct gas is generated, gathered in respective receiving hole 401 of the cover pallet 404 and covers on the surface of the row bars. Since gas-diluting recesses 403 are formed on the top surface 409 of the cover pallet 404 and communicate the respective receiving hole 401 and these recesses 403 are closer to four corners of the short row bars (for example 1^{st} row bar and 56^{th} row bar shown in FIG. 1c), the byproduct gas will be diluted by the recesses 403 during the whole process and therefore, less even no density increment of the byproduct gas will happen at the four corners of the short row bars, thus obtaining a uniform byproduct gas flow in the receiving hole 401 and finally, improving whole etching uniformity of the total row bars.

FIGS. 5a-5e demonstrates experimental effects of the wafer holding device of the prior art and the invention. Referring to FIG. 5a, curve 505 shows etching depths of the whole row bars (from row bar 01 to row bar 56) mounted on a same wafer jig of a conventional wafer holding device. As can be seen, the curve 505 has a big curvature, meaning that the conventional wafer holding device causes a big etching uniformity variation among the whole row bars. Similarly, as shown in FIG. 5b, curve 501 above indicates etching depths of a short row bar (e.g. 1st row bar shown in FIG. 1c) along its entire length, while curve 502 below indicates those of a long row bar (e.g. 29^{th} row bar shown in FIG. 1c). The two curves 501 and 502 are divergent with each other clearly, meaning that the long row bars and short row bars have different etching uniformity. Moreover, both the curves 501, 502 suffer from big curvature, indicating that etching uniformity of an individual row bar is bad from its two distal ends to the central region.

By comparison, as shown in FIG. 5c, curve 503 representing etching uniformity of a long row bar and curve 504 representing that of a short row bar (both of the row bars being placed on a same wafer jig of a wafer holding device of the invention) coincide with each other perfectly. This coincidence shows that the wafer holding device can realize a good etching uniformity over the entire row bars. In addition, the curves 503, 504 are substantially of a straight-line, showing that an individual row bar gets good etching uniformity along its whole length from its two distal ends to the central region thereof.

FIG. 5d illustrates overall etching uniformity of a group of row bars obtained by prior art and the invention respectively. The overall etching uniformity parameters include standard variation (expressed by 3 Sigma (%)) and uniformity (Max-Min) (%). The measurement points/machine include 31′ a-step and 260′ Zygo system. It can be observed that the experimental data of the invention get lower value, namely, the invention can achieve higher etching uniformity among the entire row bars mounted on the same wafer jig. Similarly, as shown in FIG. 5e, M1, M2 and M3 represent aggregate of the row bars mounted on respective one of the three wafer jigs, jig Average means etching uniformity of a particular aggregate of the row bars, whereas Batch means average etching uniformity against the total of M1, M2 and M3. In addition, both 31 points and 10 points sampling methods are used utilized to gain experimental data from the row bars secured on the wafer holding device of the invention. It can be seen that the Batch 3sigma % value of the row bars becomes smaller, demonstrating that the row bars obtain excellent uniformity among the whole row bars.

Preferably, the cover pallet is 1.25-2.5 times the thickness of the gas-diluting recess, and more preferably, the cover pallet has a thickness of 3.0-5.0 mm, and the gas-diluting recess has a thickness of 1.0-2.5 mm such that the row bars can obtain better etching uniformity along their length.

The total thickness of the cover pallet is changeable according to certain purpose. It depends on the process condition. For example, when a recipe of 3 mTorr, CF4 15 sccm STS RIE is taken, the total thickness is 3.0˜5.0 mm, and the gas-diluting recess is 1.0˜2.5 mm thick. Moreover, the relative position between the top surface of the cover pallet and the top surface of the wafer can be adjusted to get desired etch rate across the entire wafer. The gas-diluting recess is key controlling point and depends closely on the process condition so as to match/adjust etching rate uniformity.

In addition, the wafer holding device of the invention may be applied to many kinds of ion etching systems including plasma etch (PE) (such as barrel etcher, downstream etcher, parallel etcher), high density plasma (HDP) inductively coupled plasma (ICP) system, CCP system, MERIE (magnetic enhanced reactive ion etching) system and the like. Moreover, the wafer which can be held by the wafer holding device of the invention may be of any suitable material e.g. TiC—Al₂O₃, Si, SiO₂ or ceramic material.

Also, it should be appreciated that though the device of the invention is described to be used in an etching process, the device may also be used in a deposition process, since the step effect also exists in a deposition process and the device can obtain similar advantages in that process. Such deposition processes may include low pressure chemical vapor deposition (LPCVD) and so on.

The invention also provides for a method for controlling etch rate of a wafer. The wafer has a surface to be etched at its peripheral region. The method comprises the steps of: providing a wafer holding device comprised of a base pallet and a cover pallet mounted on the base pallet, the cover pallet having a receiving hole defined therein; placing the wafer in the receiving hole such that a step height is formed between an inner sidewall of the receiving hole and the peripheral region of the wafer; etching the surface to be etched of the wafer; changing the step height to adjust etching rate of the wafer at its peripheral region.

The wafer holding device further comprises a base pad mounted on the base pallet and contained in the receiving hole, and a wafer jig mounted on the base pad. The wafer is mounted on the wafer jig.

Changing the step height comprises increasing the distance between the surface to be etched of the wafer and the base pallet such that the surface to be etched is higher than the inner sidewall of the cover pallet. Changing the step height may also comprise decreasing the distance between the surface to be etched of the wafer and the base pallet such that the surface to be etched is lower than the inner sidewall of the cover pallet.

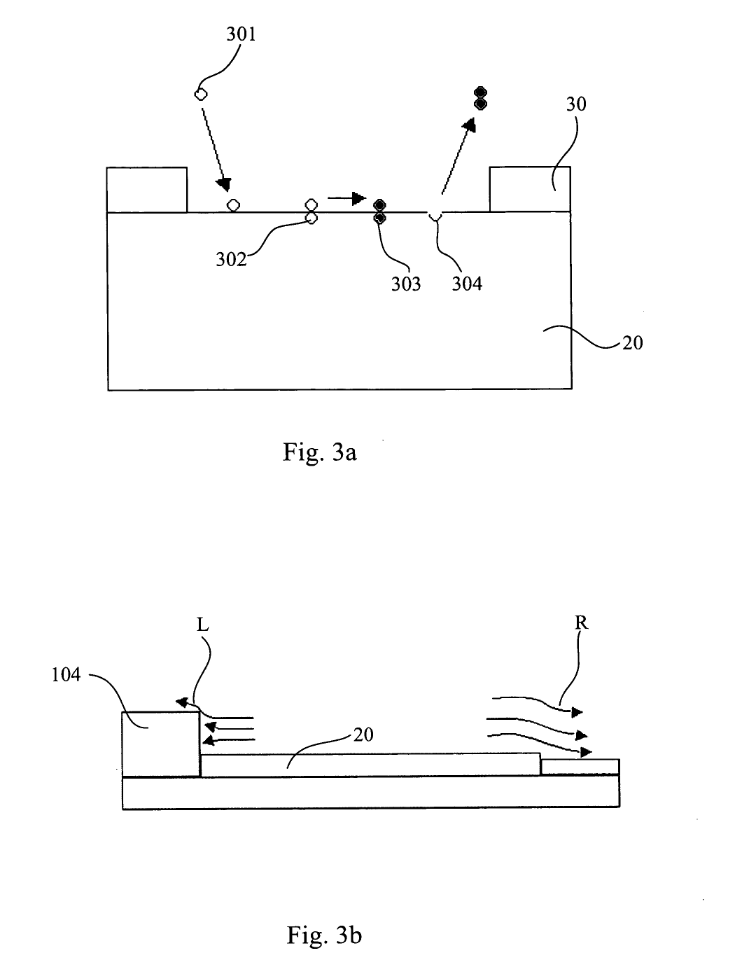

The etch rate of the wafer at its peripheral region can be accelerated if the surface to be etched is higher than the cover pallet; and can be slowed down if lower than the cover pallet. The reason is explained in BACKGROUND section in conjunction with FIG. 3b. Specifically, as shown in FIG. 3b, on one hand, if the cover pallet 104 is higher than the wafer 20, the radical species gas flow L at a distal end of a row bar will be baffled by inner wall of the receiving hole (not labeled) of the cover pallet 104, and consequently, the radical species concentration/density of the gas at this location will be decreased and more byproduct will redeposit on the substrate surface, therefore, etching rate at this distal end will be slowed down. On the other hand, if the cover pallet 104 is lower than the wafer 20, the radical species byproduct gas flow R at an opposite distal end will flow faster than at the central region, thus bringing more radical species to expedite the reaction, and accordingly, etching rate at this distal end will get faster than the central region.

Changing the step height is accomplished by adjusting thickness of the base pad. Namely, the step height can be increased if a thick base pad is used in the wafer holding device such that the surface to be etched is higher than the cover pallet; and the step height can be decreased by using a thinner base pad so that the surface to be etched of the wafer is lower than the cover pallet.

While the invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention.

What is claimed is:

1. A wafer holding device for etching process, comprising:
a base pallet;
a cover pallet disposed on the base pallet, the cover pallet having at least one receiving hole defined therein;
a base pad located on the base pallet and contained in the receiving hole of the cover pallet; and
a wafer jig placed on the base pad and contained in the receiving hole for carrying a wafer to be processed by the etching process; wherein
at least one gas-diluting recess is formed in a surface of the cover pallet away from the base pallet, the gas-diluting recess being communicated with the receiving hole to dilute byproduct gases generated during the etching process.

2. The wafer holding device according to claim 1, wherein the number of the gas-diluting recesses is four, the receiving hole is a circular receiving hole, and the four gas-diluting recesses are evenly distributed around the circular receiving hole.

3. The wafer holding device according to claim 1, wherein the cover pallet is of a circular shape, the number of the receiving holes is three, and the receiving holes are evenly distributed around the center of the circular cover pallet.

4. The wafer holding device according to claim 1, wherein the cover pallet is made of aluminum, stainless steel or ceramic material.

5. The wafer holding device according to claim 1, wherein the gas-diluting recess is of approximately a triangular shape.

6. The wafer holding device according to claim 1, wherein the cover pallet is 1.25-2.5 times the thickness of the gas-diluting recess.

7. The wafer holding device according to claim 6, wherein the cover pallet has a thickness of 3.0-5.0 mm, and the gas-diluting recess has a thickness of 1.0-2.5 mm.

8. A method for controlling etch rate of a wafer having a surface to be etched at its peripheral region during an etching process, comprising the steps of:
providing a wafer holding device comprised of a base pallet and a cover pallet mounted on the base pallet, the cover pallet having a receiving hole defined therein;
placing the wafer in the receiving hole such that a step height is formed between an inner sidewall of the receiving hole and the peripheral region of the wafer;
etching the surface to be etched of the wafer;
changing the step height to adjust etching rate of the wafer at its peripheral region.

9. The method according to claim 8, wherein the wafer holding device further comprising a base pad mounted on the base pallet and contained in the receiving hole, and a wafer jig mounted on the base pad; wherein the wafer is mounted on the wafer jig.

10. The method according to claim 8, wherein changing the step height comprises increasing the distance between the surface to be etched of the wafer and the base pallet such that the surface to be etched is higher than the inner sidewall of the cover pallet.

11. The method according to claim 8, wherein changing the step height comprises decreasing the distance between the surface to be etched of the wafer and the base pallet such that the surface to be etched is lower than the inner sidewall of the cover pallet.

12. The method according to claim 9, wherein changing the step height is accomplished by adjusting thickness of the base pad.
